(19) United States
(12) Patent Application Publication
(10) Pub. No.: US 2026/0164713 A1
(43) Pub. Date: Jun. 11, 2026

(54) SHARED CONTACT FOR STACKED FIELD EFFECT TRANSISTOR

(71) Applicant: INTERNATIONAL BUSINESS MACHINES CORPORATION, ARMONK, NY (US)

(72) Inventors: Min Gyu Sung, Latham, NY (US); Tao Li, Slingerlands, NY (US); Ruilong Xie, Niskayuna, NY (US); Nicolas Jean Loubet, GUILDERLAND, NY (US)

(21) Appl. No.: 18/969,728

(22) Filed: Dec. 5, 2024

(51) Int. Cl. H10D 30/67; H10D 30/00; H10D 30/40; H10D 62/10; H10D 84/85

(52) U.S. Cl. CPC H10D 30/6729; H10D 30/40; H10D 30/501; H10D 30/6735; H10D 62/121; H10D 84/851

(57) ABSTRACT

According to the embodiment of the present invention, a semiconductor device comprises a first nanodevice including a plurality of first upper transistors and a plurality of first lower transistors. The first nanodevice includes a first upper source/drain and a first lower source/drain. A first source/drain contact extends upwards through the first upper source/drain and a backside source/drain contact extends downwards through the first lower source/drain. The first source/drain contact directly connects to the backside source/drain contact to form a shared source/drain contact. The first source/drain contact progressively narrows from a frontside surface to a backside surface of the first source/drain contact. The backside source/drain contact progressively narrows from a backside surface to a frontside surface of the backside source/drain contact.

### BACKGROUND

The present invention relates generally to the field of microelectronics, and more particularly to a semiconductor device structure, and a method for forming a semiconductor device.

A nanosheet (NS) is the lead device architecture in continuing CMOS scaling. However, nanosheet technology has shown issues when scaling down such that as the devices become smaller and closer together, they are interfering with each other. Furthermore, as the devices become smaller and closer together, forming the connections to a backside power network is becoming more difficult.

### SUMMARY

According to the embodiment of the present invention, a semiconductor device comprises a first nanodevice including a plurality of first upper transistors and a plurality of first lower transistors. The first nanodevice includes a first upper source/drain and a first lower source/drain. A first source/drain contact extends upwards through the first upper source/drain and a backside source/drain contact extends downwards through the first lower source/drain. The first source/drain contact directly connects to the backside source/drain contact to form a shared source/drain contact. The first source/drain contact progressively narrows from a frontside surface to a backside surface of the first source/drain contact. The backside source/drain contact progressively narrows from a backside surface to a frontside surface of the backside source/drain contact.

According to the embodiment of the present invention, a semiconductor device comprises a first nanodevice including a plurality of first upper transistors and a plurality of first lower transistors. The first nanodevice includes a first upper source/drain, a second upper source/drain, a first lower source/drain, and a second lower source/drain. A first source/drain contact extends upwards through the first upper source/drain and a backside source/drain contact extends downwards through the first lower source/drain. The first source/drain contact directly connects to the backside source/drain contact to form a shared source/drain contact. The first source/drain contact progressively narrows from a frontside surface to a backside surface of the first source/drain contact. The backside source/drain contact progressively narrows from a backside surface to a frontside surface of the backside source/drain contact. A first independent source/drain contact connects to a frontside surface of the second upper source/drain and a first independent backside source/drain contact connects to a backside surface of the second lower source/drain.

According to the embodiment of the present invention, a semiconductor device comprises a first nanodevice including a plurality of first upper transistors and a plurality of first lower transistors and a second nanodevice including a plurality of second upper transistors and a plurality of second lower transistors. The first nanodevice includes a first upper source/drain, a second upper source/drain, a first lower source/drain, and a second lower source/drain. The second nanodevice is located adjacent to and parallel to the first nanodevice. The second nanodevice includes a third upper source/drain and a third lower source/drain. A first source/drain contact extends upwards through the first upper source/drain and a backside source/drain contact extends downwards through the first lower source/drain. The first source/drain contact directly connects to the backside source/drain contact to form a shared source/drain contact. The first source/drain contact progressively narrows from a frontside surface to a backside surface of the first source/drain contact. The backside source/drain contact progressively narrows from a backside surface to a frontside surface of the backside source/drain contact. A first independent source/drain contact and a second independent source/drain contact connect to a frontside surface of the second upper source/drain and the third upper source/drain, respectively. A first independent backside source/drain contact and a second independent backside source/drain contact connect to a backside surface of the second lower source/drain and the third lower source/drain, respectively.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a top-down view of a plurality of nanodevices, in accordance with the embodiment of the present invention.

FIGS. 2-4 illustrate cross sections X, Y₁, and Y₂, respectively, of the plurality of nanodevices after interlayer dielectric (ILD) deposition, nanosheet formation, shallow trench isolation (STI) region formation, gate formation, gate spacer and inner spacer formation, middle dielectric isolation (MDI) layer formation, source/drain formation, etch stop layer formation, sacrificial placeholder formation, protective liner formation, gate cut dielectric pillar formation, and CMP, in accordance with the embodiment of the present invention.

FIGS. 5-7 illustrate cross sections X, Y₁, and Y₂, respectively, of the plurality of nanodevices after the formation of a first source/drain contact, a first independent source drain contact, and a second independent source/drain contact, in accordance with the embodiment of the present invention.

FIGS. 8-10 illustrate cross sections X, Y₁, and Y₂, respectively, of the plurality of nanodevices after the formation of a plurality of gate contacts, a plurality of frontside vias, a plurality of gate contact vias, a back-end-of-line (BEOL) layer, a bonding oxide layer, bonding to a carrier wafer, after the carrier wafer is flipped and the substrate is removed, and after backside ILD (BILD) layer deposition, and CMP, in accordance with the embodiment of the present invention.

FIGS. 11-13 illustrate cross sections X, Y₁, and Y₂, respectively, of the plurality of nanodevices after the formation of a lithography mask layer, a first trench, and a second trench, in accordance with the embodiment of the present invention.

FIGS. 14-16 illustrate cross sections X, Y₁, and Y₂, respectively, of the plurality of nanodevices after the formation of a plurality of replacement placeholders, in accordance with the embodiment of the present invention.

FIGS. 17-19 illustrate cross sections X, Y₁, and Y₂, respectively, of the plurality of nanodevices after the formation of a third trench, in accordance with the embodiment of the present invention.

FIGS. 20-22 illustrate cross sections X, Y₁, and Y₂, respectively, of the plurality of nanodevices after the formation of a backside source/drain contact, in accordance with the embodiment of the present invention.

FIGS. 23-25 illustrate cross sections X, Y₁, and Y₂, respectively, of the plurality of nanodevices after the formation of a fourth trench and a fifth trench, in accordance with the embodiment of the present invention.

FIGS. 26-28 illustrate cross sections X, Y₁, and Y₂, respectively, of the plurality of nanodevices after the formation of a first independent backside source/drain contact and a second independent backside source/drain contact, in accordance with the embodiment of the present invention.

FIGS. 29-31 illustrate cross sections X, Y₁, and Y₂, respectively, of the plurality of nanodevices after the formation of a plurality of backside vias and a backside interconnect, in accordance with the embodiment of the present invention.

FIGS. 32-33 illustrate cross sections X and Y₁, respectively, of the plurality of nanodevices after ILD and additional ILD deposition, BILD layer and additional BILD layer deposition, nanosheet formation, STI region formation, gate formation, gate spacer and inner spacer formation, MDI layer formation, source/drain formation, protective liner formation, source/drain contact and independent source/drain contact formation, backside source/drain contact and independent backside source/drain contact formation, frontside via and backside via formation, BEOL layer formation, bonding oxide layer formation, carrier wafer formation, and backside interconnect formation, in accordance with the embodiment of the present invention.

FIGS. 34-35 illustrate cross sections X and Y₁, respectively, of the plurality of nanodevices after ILD and additional ILD deposition, frontside isolation ILD deposition, BILD layer and additional BILD layer deposition, nanosheet formation, STI region formation, gate formation, gate spacer and inner spacer formation, MDI layer formation, source/drain formation, protective liner formation, source/drain contact and independent source/drain contact formation, backside source/drain contact and independent backside source/drain contact formation, frontside via and backside via formation, BEOL layer formation, bonding oxide layer formation, carrier wafer formation, and backside interconnect formation, in accordance with the embodiment of the present invention.

FIGS. 36-37 illustrate cross sections X and Y₁, respectively, of the plurality of nanodevices after ILD and additional ILD deposition, BILD layer and additional BILD layer deposition, backside isolation ILD deposition, nanosheet formation, STI region formation, gate formation, gate spacer and inner spacer formation, MDI layer formation, source/drain formation, protective liner formation, source/drain contact and independent source/drain contact formation, backside source/drain contact and independent backside source/drain contact formation, frontside via and backside via formation, BEOL layer formation, bonding oxide layer formation, carrier wafer formation, and backside interconnect formation, in accordance with the embodiment of the present invention.

FIGS. 38-39 illustrate cross sections X and Y₁, respectively, of the plurality of nanodevices after ILD and additional ILD deposition, frontside isolation ILD deposition, BILD layer and additional BILD layer deposition, backside isolation ILD deposition, nanosheet formation, STI region formation, gate formation, gate spacer and inner spacer formation, MDI layer formation, source/drain formation, protective liner formation, source/drain contact and independent source/drain contact formation, backside source/drain contact and independent backside source/drain contact formation, frontside via and backside via formation, BEOL layer formation, bonding oxide layer formation, carrier wafer formation, and backside interconnect formation, in accordance with the embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes which are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

Aspect 1. A semiconductor device comprises a first nanodevice including a plurality of first upper transistors and a plurality of first lower transistors, where the first nanodevice includes a first upper source/drain and a first lower source/drain. A first source/drain contact extends upwards through the first upper source/drain and a backside source/drain contact extending downwards through the first lower source/drain, where the first source/drain contact directly connects to the backside source/drain contact to form a shared source/drain contact, where the first source/drain contact progressively narrows from a frontside surface to a backside surface of the first source/drain contact, and where the backside source/drain contact progressively narrows from a backside surface to a frontside surface of the backside source/drain contact. This embodiment has the advantage of allowing for a larger critical dimension of the shared source/drain contact, thereby reducing the resistance of the shared source/drain contact.

Aspect 2. The semiconductor device of aspect 1, where the semiconductor device may further comprise a first frontside via connected to the frontside surface of the first source/drain contact, and a first backside via connected to the backside surface of the backside source/drain contact. This embodiment has the advantage of optimizing the shared source/drain contact from a frontside and a backside of the semiconductor device.

Aspect 3. The semiconductor device of any of the preceding aspects, where the semiconductor device may further comprise a back-end-of-line (BEOL) layer connected to a frontside surface of the first frontside via, and a backside interconnect connected to a backside surface of the first backside via. This embodiment has the advantage of optimizing the shared source/drain contact from a frontside and a backside of the semiconductor device.

Aspect 4. The semiconductor device of any of the preceding aspects, where the first source/drain contact may be comprised of a first conductive metal and the backside source/drain contact may be comprised of a second conductive metal, and where the first conductive metal may be different from the second conductive metal. This embodiment has the advantage of optimizing the shared source/drain contact from a frontside and a backside of the semiconductor device.

Aspect 5. The semiconductor device of any of the preceding aspects, where the semiconductor device may further comprise a first frontside via connected to the frontside surface of the first source/drain contact, a BEOL layer connected to a frontside surface of the first frontside via, a first backside via connected to the backside surface of the backside source/drain contact, and a backside interconnect connected to a backside surface of the first backside via. This embodiment has the advantage of optimizing the shared source/drain contact from a frontside and a backside of the semiconductor device.

Aspect 6. The semiconductor device of any of the preceding aspects, where the semiconductor device may further comprise a first backside via connected to the backside surface of the backside source/drain contact, a backside interconnect connected to a backside surface of the first backside via, a frontside isolation interlayer dielectric (ILD) in direct contact with the frontside surface of the first source/drain contact, and a BEOL layer in direct contact with a frontside surface of the frontside isolation ILD. This embodiment has the advantage of optimizing the shared source/drain contact from a frontside and a backside of the semiconductor device.

Aspect 7. The semiconductor device of any of the preceding aspects, where the semiconductor device may further comprise a first frontside via connected to the frontside surface of the first source/drain contact, a BEOL layer connected to a frontside surface of the first frontside via, a backside isolation ILD in direct contact with the backside surface of the backside source/drain contact, and a backside interconnect in direct contact with a backside surface of the backside isolation ILD. This embodiment has the advantage of optimizing the shared source/drain contact from a frontside and a backside of the semiconductor device.

Aspect 8. The semiconductor device of any of the preceding aspects, where the semiconductor device may further comprise a frontside isolation ILD in direct contact with the frontside surface of the first source/drain contact, a BEOL layer in direct contact with a frontside surface of the frontside isolation ILD, a backside isolation ILD in direct contact with the backside surface of the backside source/drain contact, and a backside interconnect in direct contact with a backside surface of the backside isolation ILD. This embodiment has the advantage of optimizing the shared source/drain contact from a frontside and a backside of the semiconductor device.

Aspect 9. A semiconductor device comprises a first nanodevice including a plurality of first upper transistors and a plurality of first lower transistors, where the first nanodevice includes a first upper source/drain, a second upper source/drain, a first lower source/drain, and a second lower source/drain. A first source/drain contact extends upwards through the first upper source/drain and a backside source/drain contact extending downwards through the first lower source/drain, where the first source/drain contact directly connects to the backside source/drain contact to form a shared source/drain contact, where the first source/drain contact progressively narrows from a frontside surface to a backside surface of the first source/drain contact, and where the backside source/drain contact progressively narrows from a backside surface to a frontside surface of the backside source/drain contact. A first independent source/drain contact connects to a frontside surface of the second upper source/drain and a first independent backside source/drain contact connects to a backside surface of the second lower source/drain. This embodiment has the advantage of allowing for a larger critical dimension of the shared source/drain contact, thereby reducing the resistance of the shared source/drain contact.

Aspect 10. The semiconductor device of any of the preceding aspects, where the semiconductor device may further comprise a first frontside via connected to the frontside surface of the first source/drain contact and a second frontside via connected to a frontside surface of the first independent source/drain contact, and a first backside via connected to the backside surface of the backside source/drain contact and a second backside via connected to a backside surface of the first independent backside source/drain contact. This embodiment has the advantage of optimizing the shared source/drain contact from a frontside and a backside of the semiconductor device.

Aspect 11. The semiconductor device of any of the preceding aspects, where the semiconductor device may further comprise a BEOL layer connected to a frontside surface of the first frontside via and a frontside surface of the second frontside via, and a backside interconnect connected to a backside surface of the first backside via and a backside surface of the second backside via. This embodiment has the advantage of optimizing the shared source/drain contact from a frontside and a backside of the semiconductor device.

Aspect 12. The semiconductor device of any of the preceding aspects, where the first source/drain contact and the first independent source/drain contact may be comprised of a first conductive metal, where the backside source/drain contact and the first independent backside source/drain contact may be comprised of a second conductive metal, and where the first conductive metal may be different from the second conductive metal. This embodiment has the advantage of optimizing the shared source/drain contact from a frontside and a backside of the semiconductor device.

Aspect 13. The semiconductor device of any of the preceding aspects, where the semiconductor device may further comprise a first frontside via connected to the frontside surface of the first source/drain contact and a second frontside via connected to a frontside surface of the first independent source/drain contact, a BEOL layer connected to a frontside surface of the first frontside via and a frontside surface of the second frontside via, a first backside via connected to the backside surface of the backside source/drain contact and a second backside via connected to a backside surface of the first independent backside source/drain contact, and a backside interconnect connected to a backside surface of the first backside via and a backside surface of the second backside via. This embodiment has the advantage of optimizing the shared source/drain contact from a frontside and a backside of the semiconductor device.

Aspect 14. The semiconductor device of any of the preceding aspects, where the semiconductor device may further comprise a first backside via connected to the backside surface of the backside source/drain contact and a second backside via connected to a backside surface of the first independent backside source/drain contact, a backside interconnect connected to a backside surface of the first backside via and a backside surface of the second backside via, a frontside isolation ILD in direct contact with the frontside surface of the first source/drain contact, a frontside via connected to a frontside surface of the first independent source/drain contact, and a BEOL layer in direct contact with a frontside surface of the frontside isolation ILD and a frontside surface of the frontside via. This embodiment has the advantage of optimizing the shared source/drain contact from a frontside and a backside of the semiconductor device.

Aspect 15. The semiconductor device of any of the preceding aspects, where the semiconductor device may further comprise a first frontside via connected to the frontside surface of the first source/drain contact and a second frontside via connected to a frontside surface of the first independent source/drain contact, a BEOL layer connected to a frontside surface of the first frontside via and a frontside surface of the second frontside via, a backside isolation ILD in direct contact with the backside surface of the backside source/drain contact, a backside via connected to a backside surface of the first independent backside source/drain contact, and a backside interconnect in direct contact with a backside surface of the backside isolation ILD and a backside surface of the backside via. This embodiment has the advantage of optimizing the shared source/drain contact from a frontside and a backside of the semiconductor device.

Aspect 16. The semiconductor device of any of the preceding aspects, where the semiconductor device may further comprise a frontside isolation ILD in direct contact with the frontside surface of the first source/drain contact, a frontside via connected to a frontside surface of the first independent source/drain contact, a BEOL layer in direct contact with a frontside surface of the frontside isolation ILD and a frontside surface of the frontside via, a backside isolation ILD in direct contact with the backside surface of the backside source/drain contact, a backside via connected to a backside surface of the first independent backside source/drain contact, and a backside interconnect in direct contact with a backside surface of the backside isolation ILD and a backside surface of the backside via. This embodiment has the advantage of optimizing the shared source/drain contact from a frontside and a backside of the semiconductor device.

Aspect 17. A semiconductor device comprises a first nanodevice including a plurality of first upper transistors and a plurality of first lower transistors and a second nanodevice including a plurality of second upper transistors and a plurality of second lower transistors. The first nanodevice includes a first upper source/drain, a second upper source/drain, a first lower source/drain, and a second lower source/drain. The second nanodevice is located adjacent to and parallel to the first nanodevice. The second nanodevice includes a third upper source/drain and a third lower source/drain. A first source/drain contact extends upwards through the first upper source/drain and a backside source/drain contact extends downwards through the first lower source/drain, where the first source/drain contact directly connects to the backside source/drain contact to form a shared source/drain contact, where the first source/drain contact progressively narrows from a frontside surface to a backside surface of the first source/drain contact, and where the backside source/drain contact progressively narrows from a backside surface to a frontside surface of the backside source/drain contact. A first independent source/drain contact and a second independent source/drain contact connect to a frontside surface of the second upper source/drain and the third upper source/drain, respectively, and a first independent backside source/drain contact and a second independent backside source/drain contact connect to a backside surface of the second lower source/drain and the third lower source/drain, respectively. This embodiment has the advantage of allowing for a larger critical dimension of the shared source/drain contact, thereby reducing the resistance of the shared source/drain contact.

Aspect 18. The semiconductor device of any of the preceding aspects, where the semiconductor device may further comprise a first frontside via connected to the frontside surface of the first source/drain contact, a second frontside via connected to a frontside surface of the first independent source/drain contact, and a third frontside via connected to a frontside surface of the second independent source/drain contact, and a first backside via connected to the backside surface of the backside source/drain contact, a second backside via connected to a backside surface of the first independent backside source/drain contact, and a third backside via connected to a backside surface of the second independent backside source/drain contact. This embodiment has the advantage of optimizing the shared source/drain contact from a frontside and a backside of the semiconductor device.

Aspect 19. The semiconductor device of any of the preceding aspects, where the semiconductor device may further comprise a BEOL layer connected to a frontside surface of the first frontside via, a frontside surface of the second frontside via, and a frontside surface of the third frontside via, and a backside interconnect connected to a backside surface of the first backside via, a backside surface of the second backside via, and a backside surface of the third backside via. This embodiment has the advantage of optimizing the shared source/drain contact from a frontside and a backside of the semiconductor device.

Aspect 20. The semiconductor device of any of the preceding aspects, where the shared source/drain contact may extend a first height perpendicular to a y-axis, where the first independent source/drain contact and the first independent backside source/drain contact may each extend a second height perpendicular to the y-axis, and where the first height may be greater than the second height. This embodiment has the advantage of optimizing the shared source/drain contact from a frontside and a backside of the semiconductor device.

Currently in CMOS circuits, there is no sound solution for shared source/drain contact formation. By forming a deep independent source/drain contact in a stacked field effect transistor (FET) from a frontside of a nanodevice, a small critical dimension of a backside of the deep independent source/drain contact results in high resistance source/drain contact.

By forming a source/drain contact from a frontside of the nanodevice and another source/drain contact from a backside of the nanodevice that are connected to each other (e.g., a shared source/drain contact), a critical dimension of the shared source/drain contact may be larger than a critical dimension of the deep independent source/drain contact. The present invention does not require that all advantages need to be incorporated into every embodiment of the invention.

The present invention is directed to forming a shared contact in a stacked FET. The shared contact is formed through a multistage processing, where the first stage fills a plurality of trenches formed during middle-of-line (MOL) processing with a conductive metal, forming a first source/drain contact, a first independent source/drain contact, and a second independent source/drain contact. The second stage forms a first frontside via, a second frontside via, and a third frontside via above the first source/drain contact, the first independent source/drain contact, and the second independent source/drain contact, respectively. The third stage forms a back-end-of-line (BEOL) layer above the first frontside via, the second frontside via, and the third frontside via. The fourth stage forms a first trench and a second trench by removing a second sacrificial placeholder and a third sacrificial placeholder, respectively. The fifth stage forms a third trench by removing a first sacrificial placeholder. The sixth stage fills the third trench with the conductive metal to form a backside source/drain contact. The seventh stage forms a fourth trench and a fifth trench by removing a first replacement placeholder and a second replacement placeholder, respectively. The eighth stage fills the fourth trench and the fifth trench with the conductive metal, forming the first independent backside source/drain contact and the second independent backside source/drain contact, respectively. The ninth stage forms a first backside via, a second backside via, and a third backside via above the first independent backside source/drain contact, the backside source/drain contact, and the second independent backside source/drain contact, respectively. The tenth stage forms a backside interconnect above the first backside via, the second backside via, and the third backside via.

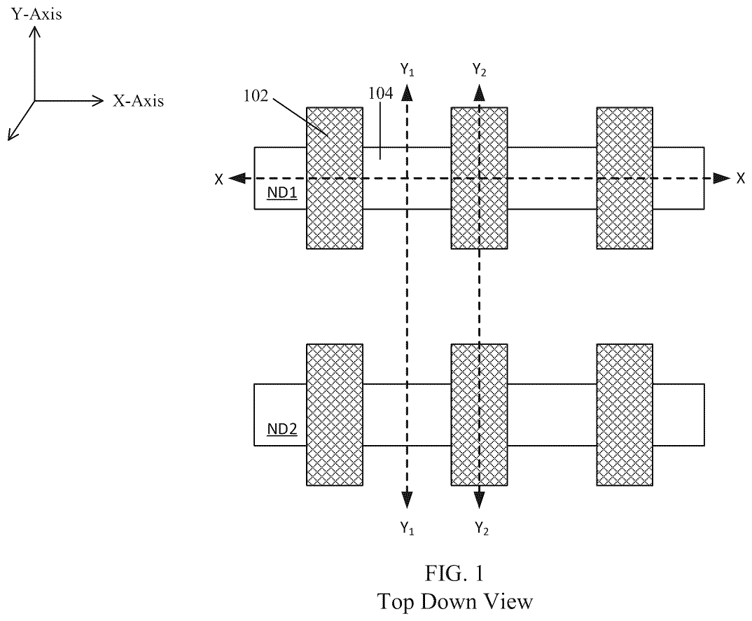

FIG. 1 illustrates a top-down view of a plurality of nanodevices ND1, ND2, in accordance with the embodiment of the present invention. The adjacent and parallel devices include a first nanodevice ND1 including a plurality of first upper transistors and a plurality of first lower transistors, and a second nanodevice ND2 including a plurality of second upper transistors and a plurality of second lower transistors. Cross-section X is a cross section perpendicular to the gates along the horizontal axis of the first nanodevice ND1. Cross-section Y₁ is a cross section parallel to the gates in the source/drain region 104 across the plurality of nanodevices ND1, ND2. Cross-section Y₂ is a cross section parallel to the gates in the gate region 102 across the plurality of nanodevices ND1, ND2. It may be appreciated that the embodiment of the present invention is not limited to nanodevices ND1, ND2 and that other devices including, but not limited to, nanosheet transistors, FinFET, nanowire, and a planar device may also be used.

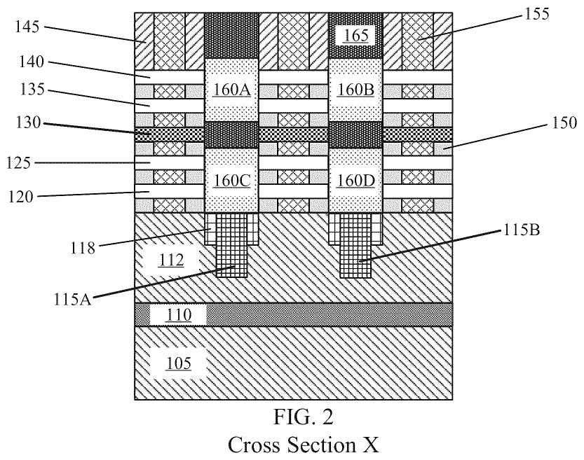

FIGS. 2-4 illustrate cross sections X, Y₁, and Y₂, respectively, of the plurality of nanodevices ND1, ND2 after interlayer dielectric (ILD) 165 deposition, nanosheet 120, 125, 135, 140 formation, shallow trench isolation (STI) region 114 formation, gate 155 formation, gate spacer 145 and inner spacer 150 formation, middle dielectric isolation (MDI) layer 130 formation, source/drain 160A, 160B, 160C, 160D, 160E, 160F formation, etch stop layer 110 formation, sacrificial placeholder 115A, 115B, 115C formation, protective liner 118 formation, gate cut dielectric pillar 170, 175, 180 formation, and CMP, in accordance with the embodiment of the present invention. The plurality of nanodevices ND1, ND2 include a substrate 105, an etch stop layer 110, an underlying substrate layer 112, an STI region 114, a first lower nanosheet 120, a second lower nanosheet 125, a first upper nanosheet 135, and a second upper nanosheet 140. As used herein, the terms “upper” and “lower” refer to the orientation of structures prior to a wafer flip. Thus, structures above the MDI layer 130 prior to the wafer flip are referred to as “upper” and structures below the MDI layer 130 prior to the wafer flip are referred to as “lower.” The substrate 105 and the etch stop layer 110 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 and the etch stop layer 110 may be doped, undoped or contain doped regions and undoped regions therein. A portion of the underlying substrate layer 112 is selectively removed and a material (e.g., SiGe) is deposited in a space created by the removal of the portion of the underlying substrate layer 112 to form the first sacrificial placeholder 115A, the second sacrificial placeholder 115B, the third sacrificial placeholder 115C, and the protective liner 118 along a portion of sidewalls of the first sacrificial placeholder 115A, the second sacrificial placeholder 115B, the third sacrificial placeholder 115C.

The first sacrificial layer (not shown) is formed directly atop the underlying substrate layer 112. The second sacrificial layer (not shown) is formed directly atop the first sacrificial layer (not shown). The first lower nanosheet 120 is formed directly atop the second sacrificial layer (not shown). The third sacrificial layer (not shown) is formed directly atop the first lower nanosheet 120. The second lower nanosheet 125 is formed directly atop the third sacrificial layer (not shown). The fourth sacrificial layer (not shown) is formed directly atop the second lower nanosheet 125. The MDI layer 130 is formed directly atop the fourth sacrificial layer (not shown). The fifth sacrificial layer (not shown) is formed directly atop the MDI layer 130. The first upper nanosheet 135 is formed directly atop the fifth sacrificial layer (not shown). The sixth sacrificial layer (not shown) is formed directly atop the first upper nanosheet 135. The second upper nanosheet 140 is formed directly atop the sixth sacrificial layer (not shown). The first sacrificial layer (not shown), the second sacrificial layer (not shown), the third sacrificial layer (not shown), the fourth sacrificial layer (not shown), the fifth sacrificial layer (not shown), and the sixth sacrificial layer (not shown) are hereinafter referred to as the plurality of sacrificial layers (not shown). In addition, the first lower nanosheet 120 and the second lower nanosheet 125 are hereinafter referred to as the plurality of lower nanosheets 120, 125, and the first upper nanosheet 135 and the second upper nanosheet 140 are hereinafter referred to as the plurality of upper nanosheets 135, 140. The plurality of sacrificial layers (not shown) may be comprised of, for example, SiGe, where Ge is about 35%. The plurality of lower nanosheets 120, 125 and the plurality of upper nanosheets 135, 140 may be comprised of, for example, Si. The number of nanosheets and the number of sacrificial layers described above are not intended to be limiting, and it may be appreciated that in the embodiment of the present invention the number of nanosheets and the number of sacrificial layers may vary. After formation of the plurality of lower nanosheets 120, 125, the plurality of upper nanosheets 135, 140, and the plurality of sacrificial layers (not shown), together the nanosheet stack, the nanosheet stack (comprising alternative Si and SiGe layers) may be further patterned using conventional lithography and etching processes. After nanosheet stack formation and patterning, the STI region 114 is formed by dielectric filling, CMP, and dielectric recess.

A dummy gate material is deposited and then patterned to form dummy gates (not shown), followed by gate spacer 145 formation by a conformal dielectric liner deposition followed by anisotropic etch. Then, the nanosheet stack at the S/D region 104 is recessed, followed by indentation of sacrificial layers (not shown) and inner spacer 150 formation. Then, the first upper source/drain 160A, the second upper source/drain 160B, the first lower source/drain 160C, the second lower source/drain 160D, the third upper source/drain 160E, and the third lower source/drain 160F are epitaxially grown over exposed sidewalls of the plurality of lower nanosheets 120, 125 and the plurality of upper nanosheets 135, 140, followed by ILD 165 deposition and CMP to remove a dummy gate hard mask (not shown). Then, the sacrificial layers (not shown) are removed, followed by gate 155 formation. The first lower source/drain 160C, the second lower source/drain 160D, and the third lower source/drain 160F are formed directly atop the first sacrificial placeholder 115A, the second sacrificial placeholder 115B, and the third sacrificial placeholder 115C, respectively, and the protective liner 118. The first upper source/drain 160A, the second upper source/drain 160B, and the third upper source/drain 160E are formed over the first lower source/drain 160C, the second lower source/drain 160D, and the third lower source/drain 160F, respectively, within the ILD 165.

The first upper source/drain 160A, the second upper source/drain 160B, the first lower source/drain 160C, the second lower source/drain 160D, the third upper source/drain 160E, and the third lower source/drain 160F can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

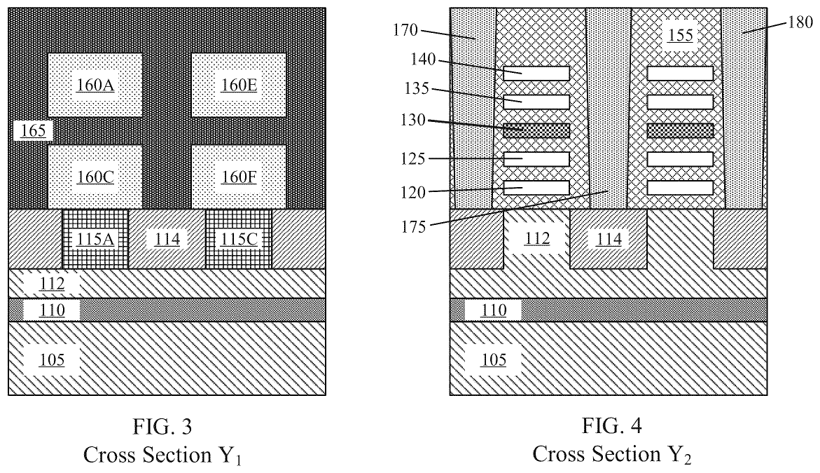

In FIG. 2, the ILD 165 is formed directly atop the first upper source/drain 160A, the second upper source/drain 160B, the first lower source/drain 160C, and the second lower source/drain 160D, and surrounds one side of the gate spacer 145, the MDI layer 130, and a portion of the inner spacer 150. In FIG. 3, the ILD 165 is formed directly atop the first upper source/drain 160A, the first lower source/drain 160C, the third upper source/drain 160E, and the third lower source/drain 160F, and the STI region 114.

In FIG. 2, a gate material is deposited in the space created by the removal of the plurality of sacrificial layers (not shown) and directly atop the second upper nanosheet 140 to form a replacement gate (i.e., the gate 155). In FIG. 4, the gate material is deposited in the space created by the removal of the plurality of sacrificial layers (not shown), and directly atop the second upper nanosheet 140 and the STI region 114 to form the gate 155. The gate 155 can be comprised of, for example, a gate dielectric liner, such as a high-k dielectric like HfO2, ZrO2, HfLaOx, etc., and work function layers, such as TiN, TiAlC, TiC, etc., and conductive metal fills, like W. In FIG. 4, a liner material is also deposited in trenches (not shown) formed during front-end-of-line processing to form the first gate cut dielectric pillar 170, the second gate cut dielectric pillar 175, and the third gate cut dielectric pillar 180. The liner material may be comprised of, for example, SiN, SiBCN, SiOCN, SiOC, or SiC.

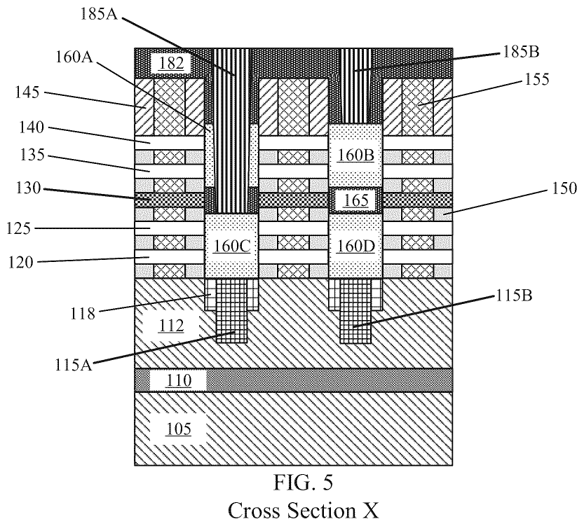

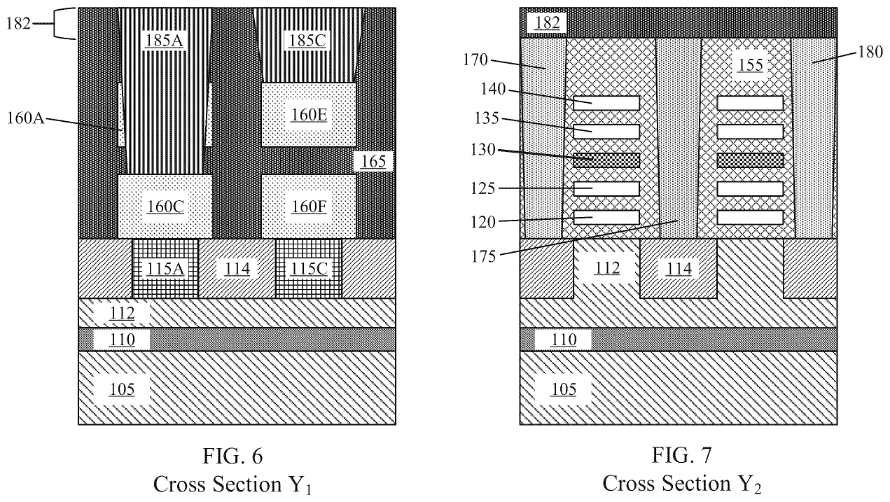

FIGS. 5-7 illustrate cross sections X, Y₁, and Y₂, respectively, of the plurality of nanodevices ND1, ND2 after the formation of a first source/drain contact 185A, a first independent source drain contact 185B, and a second independent source/drain contact 185C, in accordance with the embodiment of the present invention. In FIG. 5, an additional ILD 182 is formed directly atop the gate spacer 145, the gate 155, and the ILD 165. In FIG. 6, the additional ILD 182 is formed directly atop the ILD 165. In FIG. 7, the additional ILD is formed directly atop the gate 155 and the first gate cut dielectric pillar 170, the second gate cut dielectric pillar 175, and the third gate cut dielectric pillar 180. In FIGS. 5-6, a plurality of trenches (not shown) formed during middle-of-line (MOL) patterning are filled with a conductive metal (e.g., including a silicide liner, such as Ni, Ti, NiPt, an adhesion metal liner, such as TiN and conductive metal fill, such as W, Co, or Ru) to form the first source/drain contact 185A, the first independent source drain contact 185B, and the second independent source/drain contact 185C. The first source/drain contact 185A is located over the first lower source/drain 160C. The first independent source/drain contact 185B is located over the second upper source/drain 160B. The second independent source/drain contact 185C is located over the third upper source/drain 160E.

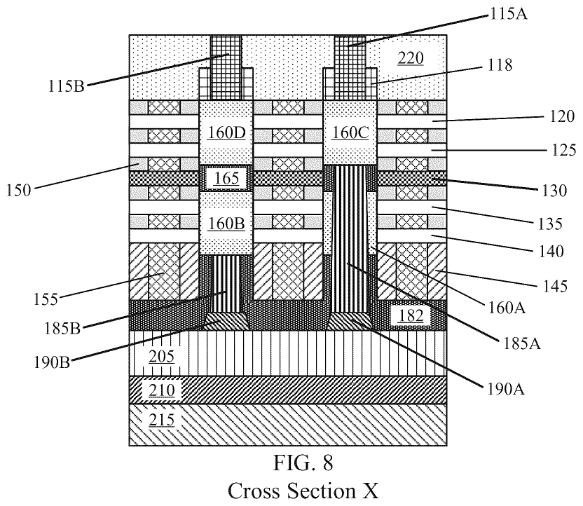

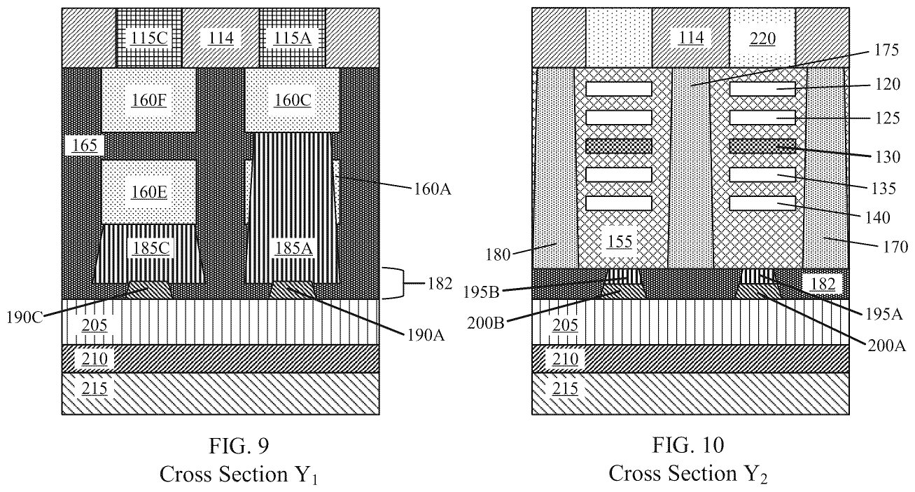

FIGS. 8-10 illustrate cross sections X, Y₁, and Y₂, respectively, of the plurality of nanodevices ND1, ND2 after the formation of a plurality of gate contacts 195A, 195B, a plurality of frontside vias 190A, 190B, 190C, a BEOL layer 205, a plurality of gate contact vias 200A, 200B, a bonding oxide layer 210, bonding to a carrier wafer 215, after the carrier wafer 215 is flipped and the substrate 105 is removed, and after backside ILD (BILD) layer 220 deposition, and CMP, in accordance with the embodiment of the present invention. Prior to a flip of the carrier wafer 215, in FIG. 10, the plurality of trenches (not shown) formed during middle-of-line (MOL) patterning are filled with the conductive metal to form the plurality of gate contacts 195A, 195B. The first gate contact 195A is located directly atop the gate 155 between the first gate cut dielectric pillar 170 and the second gate cut dielectric pillar 175. The second gate contact 195B is located directly atop the gate 155 between the second gate cut dielectric pillar 175 and the third gate cut dielectric pillar 180. In FIGS. 8-10, the plurality of frontside vias 190A, 190B, 190C and the plurality of gate contact vias 200A, 200B are patterned using conventional lithography and etching processes, followed by metallization (e.g., Cu, Co or Ru fill with adhesion liner such as TiN).

Prior to a flip of the carrier wafer 215, the first frontside via 190A is located directly atop the first source/drain contact 185A, the second frontside via 190B is located directly atop the first independent source/drain contact 185B, and the third frontside via 190C is located directly atop the second independent source/drain contact 185C. The BEOL layer 205 may contain multiple metal layers and vias in between. In FIG. 8, the BEOL layer 205 is formed directly atop the additional ILD 182, the first frontside via 190A, and the second frontside via 190B. In FIG. 9, the BEOL layer 205 is formed directly atop the additional ILD 182, the first frontside via 190A, and the third frontside via 190C. In FIG. 10, the BEOL layer 205 is formed directly atop the additional ILD 182, the first gate contact via 200A, and the second gate contact via 200B. In FIGS. 8-10, the bonding oxide layer 210 is formed directly atop the BEOL layer 205. The carrier wafer 215 is formed directly atop the bonding oxide layer 210 by bonding processes (e.g., oxide-oxide bonding). The following paragraphs discuss the processing of the backside of the substrate 105, whereas the current and previous paragraphs discuss the processing of the frontside of the substrate 105.

Then, the carrier wafer 215 is flipped and the substrate 105 is removed, in accordance with the embodiment of the present invention. The carrier wafer 215 is flipped and the carrier wafer 215 becomes a handler wafer. The substrate 105 is removed by, for example, a combination of processes such as wafer grinding, CMP, and/or selective dry/wet etch, stopping on the etch stop layer 110. The etch stop layer 110 is removed to expose the underlying substrate layer 112. The underlying substrate layer 112 is removed by, for example, a selective wet or dry etch process.

The BILD layer 220 may be comprised of, for example, SiC or SiOC. In FIG. 8, the BILD layer 220 is deposited directly atop the inner spacer 150, the gate 155, and the protective liner 118. In FIG. 10, the BILD layer 220 is deposited directly atop the gate 155. In FIGS. 8 and 10, a portion of the BILD layer 220 is selectively removed by, for example, CMP.

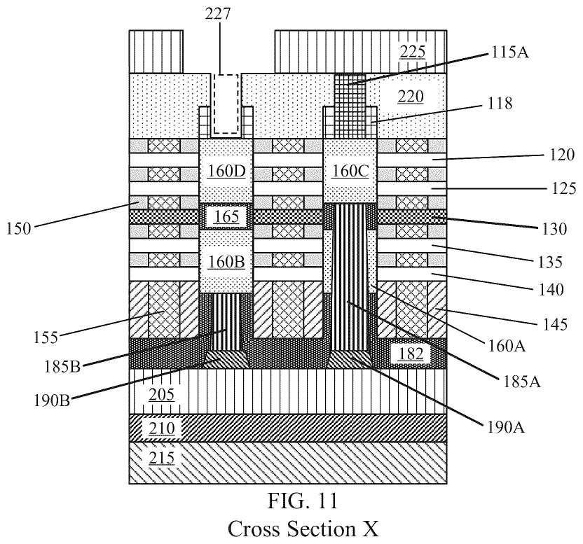

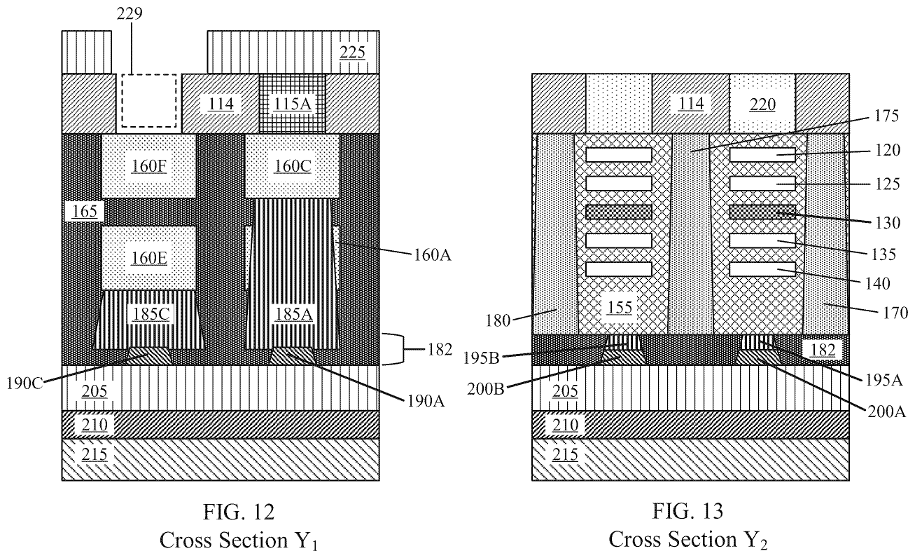

FIGS. 11-13 illustrate cross sections X, Y₁, and Y₂, respectively, of the plurality of nanodevices ND1, ND2 after the formation of a lithography mask layer 225, a first trench 227, and a second trench 229, in accordance with the embodiment of the present invention. The lithography mask layer 225 may be, for example, an organic planarization layer (OPL). In FIG. 11, the lithography mask layer 225 is deposited and then patterned directly atop the first sacrificial placeholder 115A, the second sacrificial placeholder 115B, and the BILD layer 220 to expose the second sacrificial placeholder 115B. The exposed second sacrificial placeholder 115B is etched by, for example, RIE to form the first trench 227. A bottom surface of the first trench 227 exposes a top surface of the second lower source/drain 160D. In FIG. 12, the lithography mask layer 225 is deposited and then patterned directly atop the STI region 114, the first sacrificial placeholder 115A, and the third sacrificial placeholder 115C to expose the third sacrificial placeholder 115C. The exposed third sacrificial placeholder 115C is etched by, for example, RIE to form the second trench 229. A bottom surface of the second trench 229 exposes a top surface of the third lower source/drain 160F. In FIGS. 11-12, the lithography mask layer 225 is formed by depositing, for example, an OPL material in a spin-on coating process.

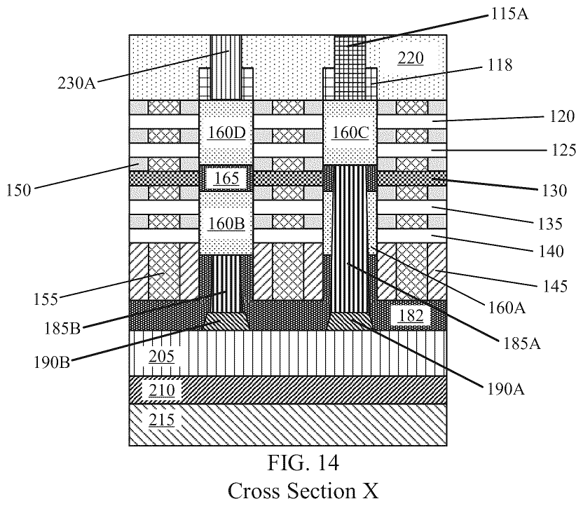

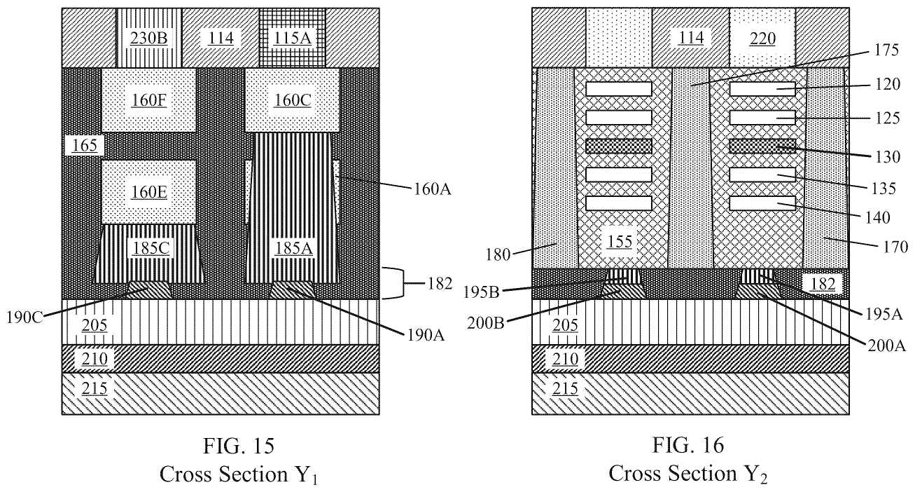

FIGS. 14-16 illustrate cross sections X, Y₁, and Y₂, respectively, of the plurality of nanodevices ND1, ND2 after the formation of a plurality of replacement placeholders 230A, 230B, in accordance with the embodiment of the present invention. In FIG. 14, the first trench 227 is filled with, for example, SiN to form the first replacement placeholder 230A. The first replacement placeholder 230A is located directly atop the second lower source/drain 160D. In FIG. 15, the second trench 229 is filled with, for example, SiN to form the second replacement placeholder 230B. The second replacement placeholder 230B is located directly atop the third lower source/drain 160F.

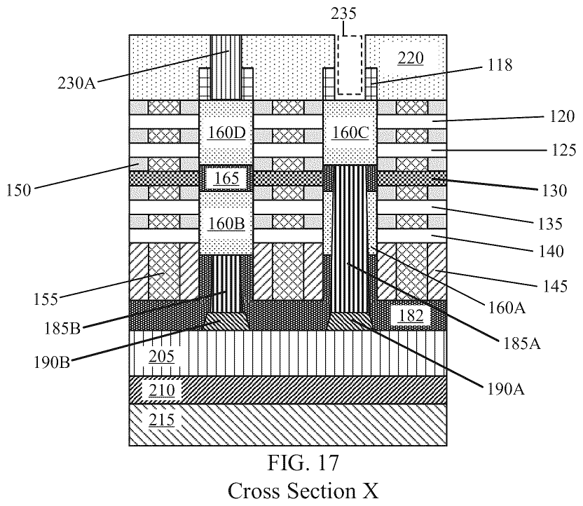

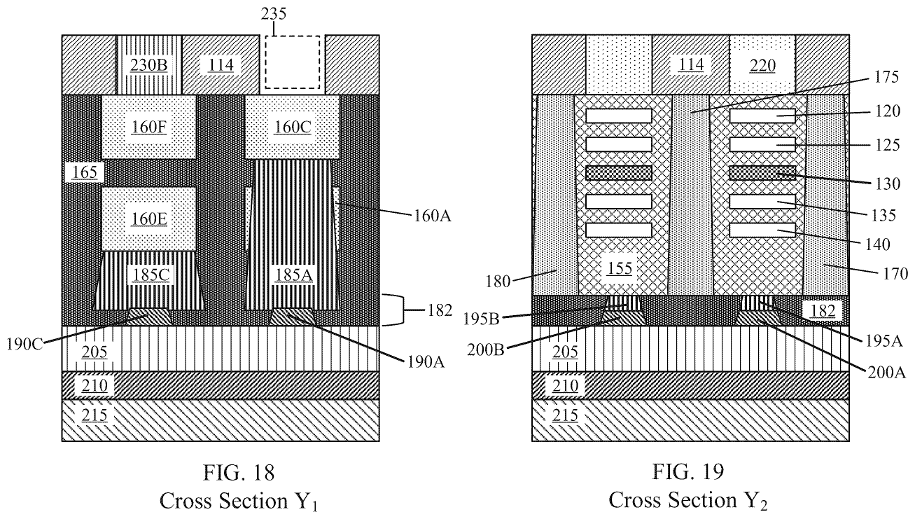

FIGS. 17-19 illustrate cross sections X, Y₁, and Y₂, respectively, of the plurality of nanodevices ND1, ND2 after the formation of a third trench 235, in accordance with the embodiment of the present invention. In FIGS. 17-18, the first sacrificial placeholder 115A is removed by, for example, RIE to form the third trench 235. A bottom surface of the third trench 235 exposes a top surface of the first lower source/drain 160C.

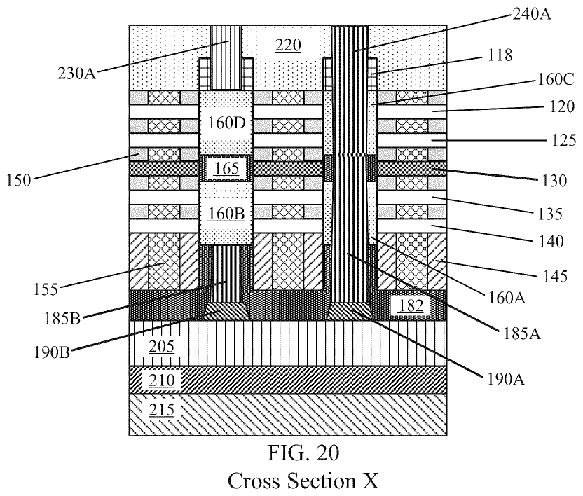

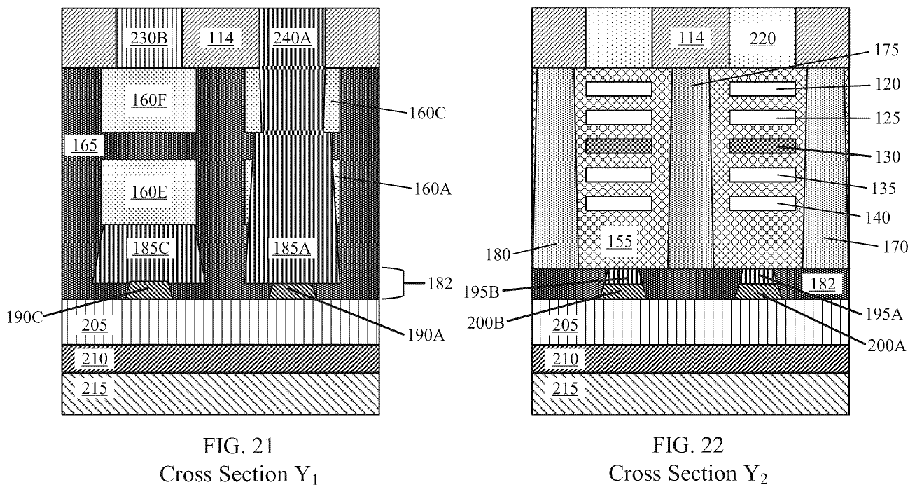

FIGS. 20-22 illustrate cross sections X, Y₁, and Y₂, respectively, of the plurality of nanodevices ND1, ND2 after the formation of a backside source/drain contact 240A, in accordance with the embodiment of the present invention. In FIGS. 20-21, the third trench 235 is filled with the conductive metal to form the backside source/drain contact 240A. The first source/drain contact 185A directly connects to the backside source/drain contact 240A to form a shared source/drain contact 185A, 240A.

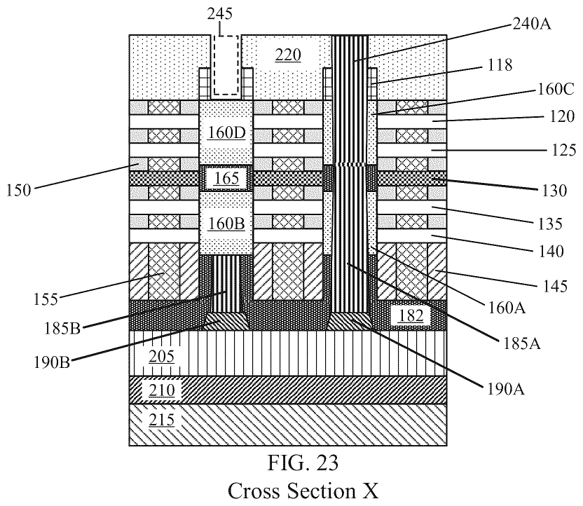

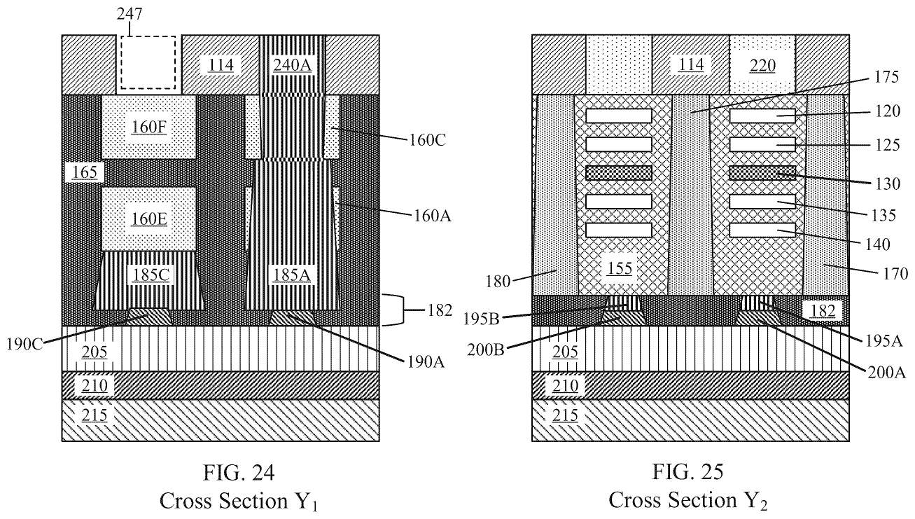

FIGS. 23-25 illustrate cross sections X, Y₁, and Y₂, respectively, of the plurality of nanodevices ND1, ND2 after the formation of a fourth trench 245 and a fifth trench 247, in accordance with the embodiment of the present invention. In FIG. 23, the first replacement placeholder 230A is removed by, for example, RIE to form the fourth trench 245. A bottom surface of the fourth trench 245 exposes a top surface of the second lower source/drain 160D. In FIG. 24, the second replacement placeholder 230B is removed by, for example, RIE to form the fifth trench 247. A bottom surface of the fifth trench 247 exposes a top surface of the third lower source/drain 160F.

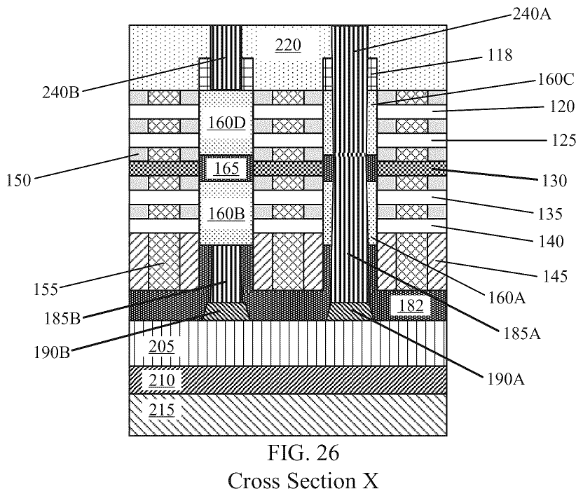

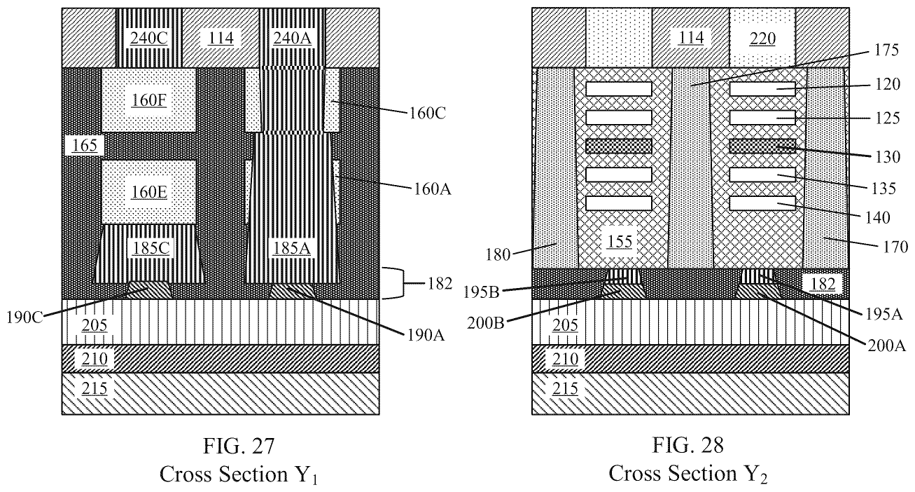

FIGS. 26-28 illustrate cross sections X, Y₁, and Y₂, respectively, of the plurality of nanodevices ND1, ND2 after the formation of a first independent backside source/drain contact 240B and a second independent backside source/drain contact 240C, in accordance with the embodiment of the present invention. In FIG. 26, the fourth trench 245 is filled with the conductive metal (e.g., including a silicide liner, such as Ni, Ti, NiPt, an adhesion metal liner, such as TiN and conductive metal fill, such as W, Co, or Ru) to form the first independent backside source/drain contact 240B. The first independent backside source/drain contact 240B is located over the second lower source/drain 160D. In FIG. 27, the fifth trench 247 is filled with the conductive metal to form the second independent backside source/drain contact 240C. The second independent backside source/drain contact 240C is located over the third lower source/drain 160F.

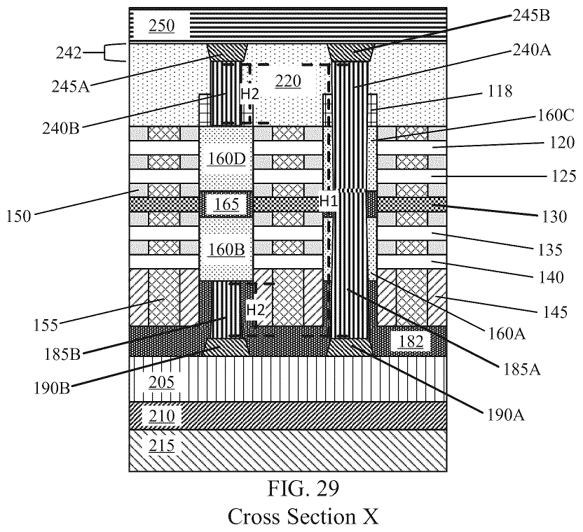

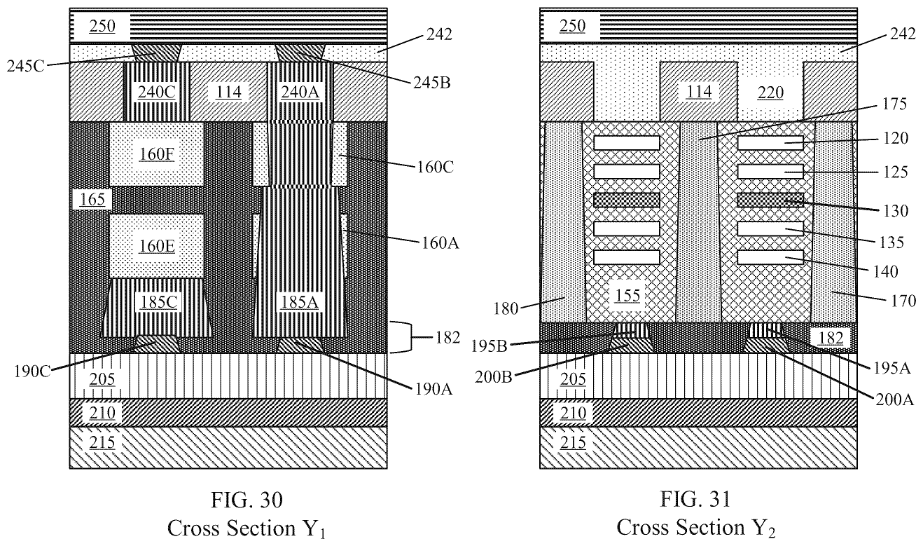

FIGS. 29-31 illustrate cross sections X, Y₁, and Y₂, respectively, of the plurality of nanodevices ND1, ND2 after the formation of a plurality of backside vias 245A, 245B, 245C and a backside interconnect 250, in accordance with the embodiment of the present invention. In FIG. 29, an additional BILD layer 242 is deposited directly atop the BILD layer 220. In FIG. 30, the additional BILD layer 242 is deposited directly atop the STI region 114, a portion of the backside source/drain contact 240A, and a portion of the first independent backside source/drain contact 240C. In FIG. 31, the additional BILD layer 242 is deposited directly atop the BILD layer 220 and the STI region 114. In FIGS. 29-30, the plurality of backside vias 245A, 245B, 245C are patterned using conventional lithography and etching processes, followed by metallization (e.g., Cu, Co or Ru fill with adhesion liner such as TiN). In FIG. 29, the first backside via 245A (i.e., the second backside via in the claims) is located directly atop the first independent backside source/drain contact 240B and the second backside via 245B (i.e., the first backside via in the claims) is located directly atop the backside source/drain contact 240A. In FIG. 30, the second backside via 245B is located directly atop the backside source/drain contact 240A and the third backside via 245C is located directly atop the second independent backside source/drain contact 240C. In FIG. 29, the backside interconnect 250 is formed directly atop the first backside via 245A, the second backside via 245B, and the additional BILD layer 242. In FIG. 30, the backside interconnect 250 is formed directly atop the second backside via 245B, the third backside via 245C, and the additional BILD layer 242. In FIG. 31, the backside interconnect 250 is formed directly atop the additional BILD layer 242.

The first source/drain contact 185A extends upwards through the first upper source/drain 160A and the backside source/drain contact 240A extends downwards through the first lower source/drain 160C. The first source/drain contact 185A directly connects to the backside source/drain contact 240A to form the shared source/drain contact 185A, 240A. The first source/drain contact 185A progressively narrows from a frontside surface to a backside surface of the first source/drain contact 185A, and the backside source/drain contact 240A progressively narrows from a backside surface to a frontside surface of the backside source/drain contact 240A. The first independent source/drain contact 185B connects to a frontside surface of the second upper source/drain 160B and a first independent backside source/drain contact 240B connects to a backside surface of the second lower source/drain 160D. The shared source/drain contact 185A, 240A extends a first height H1 perpendicular to a y-axis. The first independent source/drain contact 185B and the first independent backside source/drain contact 240B each extend a second height H2 perpendicular to the y-axis. The first height H1 is greater than the second height H2. The second independent source/drain contact 185C connects to a frontside surface of the third upper source/drain 160E, and a second independent backside source/drain contact 240C connects to a backside surface of the third lower source/drain 160F.

The first frontside via 190A connects to the frontside surface of the first source/drain contact 185A, the second frontside via 190B connects to a frontside surface of the first independent source/drain contact 185B, and a third frontside via 190C connects to a frontside surface of the second independent source/drain contact 185C. The first backside via 245A connects to a backside surface of the first independent backside source/drain contact 240B, the second backside via 245B connects to the backside surface of the backside source/drain contact 240A, and the third backside via 245C connects to a backside surface of the second independent backside source/drain contact 240C.

The BEOL layer 205 connects to a frontside surface of the first frontside via 190A, a frontside surface of the second frontside via 190B, and a frontside surface of the third backside via 190C. The backside interconnect 250 connects to a backside surface of the first backside via 245A, a backside surface of the second backside via 245B, and a backside surface of the third backside via 245C.

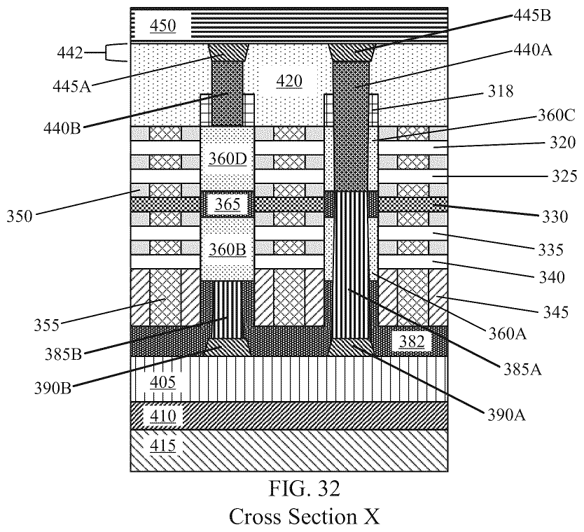

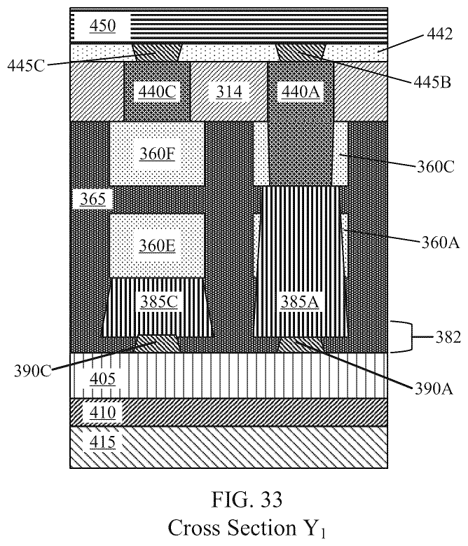

FIGS. 32-33 illustrate cross sections X and Y₁, respectively, of the plurality of nanodevices ND1, ND2 after ILD 365 and additional ILD 382 deposition, BILD layer 420 and additional BILD layer 442 deposition, nanosheet 320, 325, 335, 340 formation, STI region 114 formation, gate 355 formation, gate spacer 345 and inner spacer 350 formation, MDI layer 330 formation, source/drain 360A, 360B, 360C, 360D, 360E, 360F formation, protective liner 318 formation, source/drain contact 385A and independent source/drain contact 385B, 385C formation, backside source/drain contact 440A and independent backside source/drain contact 440B, 440C formation, frontside via 390A, 390B, 390C and backside via 445A, 445B, 445C formation, BEOL layer 405 formation, bonding oxide layer 410 formation, carrier wafer 415 formation, and backside interconnect 450 formation, in accordance with the embodiment of the present invention. The first source/drain contact 385A, the first independent source/drain contact 385B, and the second independent source/drain contact 385C may be comprised of a first conductive metal, and the backside source/drain contact 440A, the first independent backside source/drain contact 440B, and the second independent backside source/drain contact 440C may be comprised of a second conductive metal, where the first conductive metal is different from the second conductive metal. The first conductive metal may be comprised of, for example, an NiPt liner, a TiN liner, and a W or Co metal fill. The second conductive metal may be comprised of, for example, a Ti liner, a TiN liner, and a W or Co metal fill.

The first frontside via 390A connects to the frontside surface of the first source/drain contact 385A, the second frontside via 390B connects to a frontside surface of the first independent source/drain contact 385B, and the third frontside via 390C connects to a frontside surface of the second independent source/drain contact 385C. The BEOL layer 405 connects to a frontside surface of the first frontside via 390A, a frontside surface of the second frontside via 390B, and a frontside surface of the third frontside via 390C. The first backside via 445A (i.e., the second backside via in the claims) connects to a backside surface of the first independent backside source/drain contact 440B, the second backside via 445B (i.e., the first backside via in the claims) connects to the backside surface of the backside source/drain contact 440A, and the third backside via 445C connects to a backside surface of the second independent source/drain contact 440C. The backside interconnect 450 connects to a backside surface of the first backside via 445A, a backside surface of the second backside via 445B, and a backside surface of the third backside via 445C.

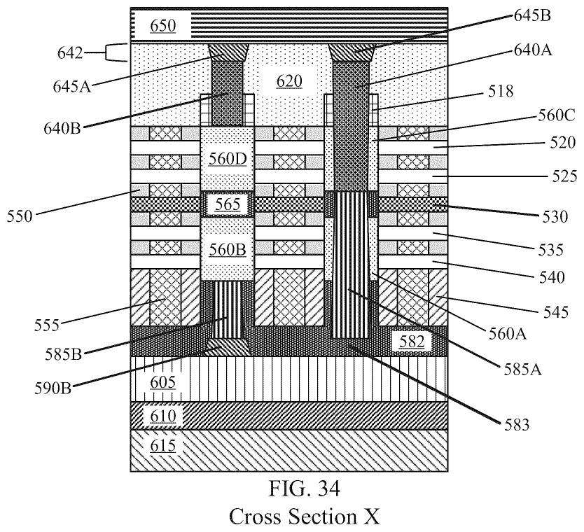

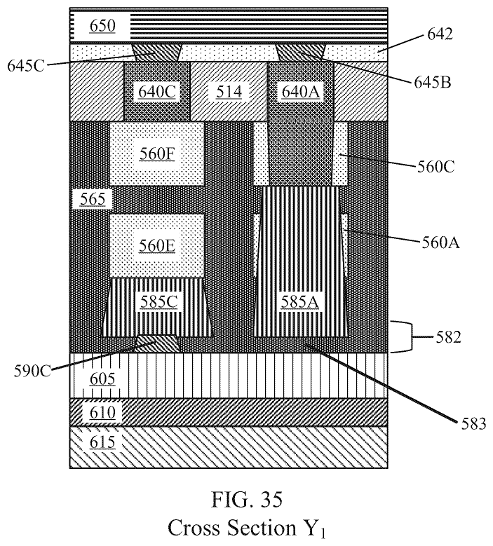

FIGS. 34-35 illustrate cross sections X and Y₁, respectively, of the plurality of nanodevices ND1, ND2 after ILD 565 and additional ILD 582 deposition, frontside isolation ILD 583 deposition, BILD layer 620 and additional BILD layer 642 deposition, nanosheet 520, 525, 535, 540 formation, STI region 514 formation, gate 555 formation, gate spacer 545 and inner spacer 550 formation, MDI layer 530 formation, source/drain 560A, 560B, 560C, 560D, 560E, 560F formation, protective liner 518 formation, source/drain contact 585A and independent source/drain contact 585B, 585C formation, backside source/drain contact 640A and independent backside source/drain contact 640B, 640C formation, frontside via 590B, 590C and backside via 645A, 645B, 645C formation, BEOL layer 605 formation, bonding oxide layer 610 formation, carrier wafer 615 formation, and backside interconnect 650 formation, in accordance with the embodiment of the present invention. The first backside via 645A (i.e., the second backside via in the claims) connects to a backside surface of the first independent backside source/drain contact 640B, the second backside via 645B (i.e., the first backside via in the claims) connects to the backside surface of the backside source/drain contact 640A, and the third backside via 645C connects to a backside surface of the second independent backside source/drain contact 640C. The backside interconnect 650 connects to a backside surface of the first backside via 645A, a backside surface of the second backside via 645B, and a backside surface of the third backside via 645C. The frontside isolation ILD 583, which may be a portion of the additional ILD 582, is in direct contact with the frontside surface of the first source/drain contact 585A. The frontside via 590B connects to a frontside surface of the first independent source/drain contact 585B. The BEOL layer 605 is in direct contact with a frontside surface of the frontside isolation ILD 583, a frontside surface of the frontside via 590B, and a frontside surface of a different frontside via 590C.

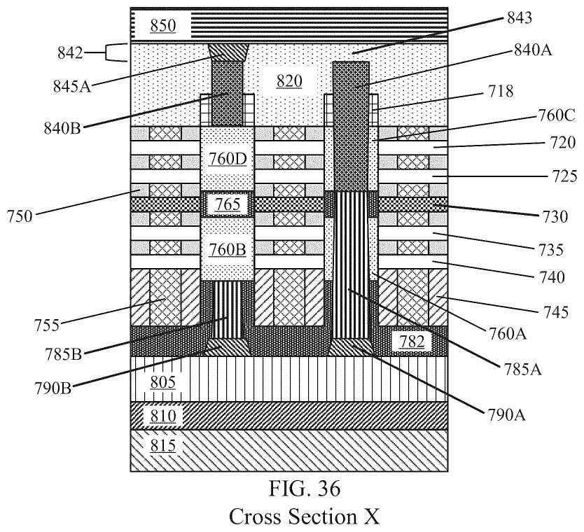

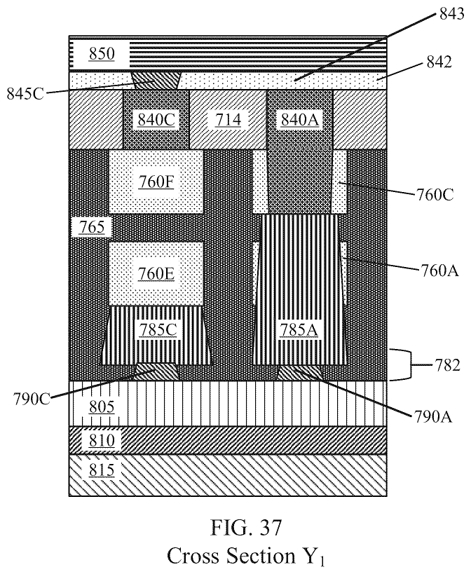

FIGS. 36-37 illustrate cross sections X and Y₁, respectively, of the plurality of nanodevices ND1, ND2 after ILD 765 and additional ILD 782 deposition, BILD layer 820 and additional BILD layer 842 deposition, backside isolation ILD 843 deposition, nanosheet 720, 725, 735, 740 formation, STI region 714 formation, gate 755 formation, gate spacer 745 and inner spacer 750 formation, MDI layer 730 formation, source/drain 760A, 760B, 760C, 760D, 760E, 760F formation, protective liner 718 formation, source/drain contact 785A and independent source/drain contact 785B, 785C formation, backside source/drain contact 840A and independent backside source/drain contact 840B, 840C formation, frontside via 790A, 790B, 790C and backside via 845A, 845C formation, BEOL layer 805 formation, bonding oxide layer 810 formation, carrier wafer 815 formation, and backside interconnect 850 formation, in accordance with the embodiment of the present invention. The first frontside via 790A connects to the frontside surface of the first source/drain contact 785A, the second frontside via 790B connects to a frontside surface of the first independent source/drain contact 785B, and a third frontside via 790C connects to a frontside surface of the second independent source/drain contact 785C. The BEOL layer 805 connects to a frontside surface of the first frontside via 790A, a frontside surface of the second frontside via 790B, and a frontside surface of the third frontside via 790C. The backside isolation ILD 843, which may be a portion of the additional BILD layer 842, is in direct contact with the backside surface of the backside source/drain contact 840A. The backside via 845A connects to a backside surface of the first independent backside source/drain contact 840B. The backside interconnect 850 is in direct contact with a backside surface of the backside isolation ILD 843, a backside surface of the backside via 845A, and a backside surface of a different backside via 845C.

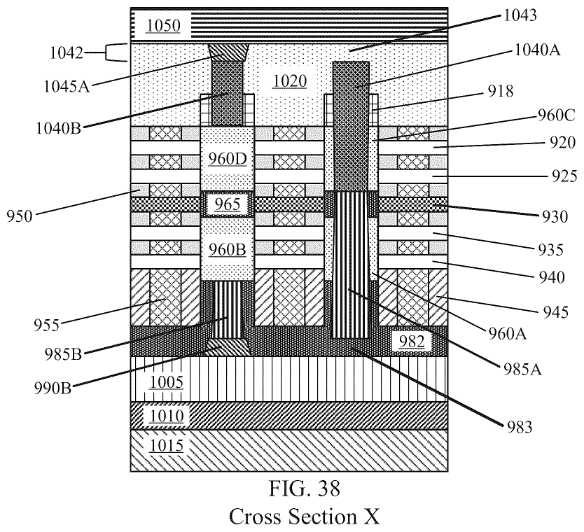

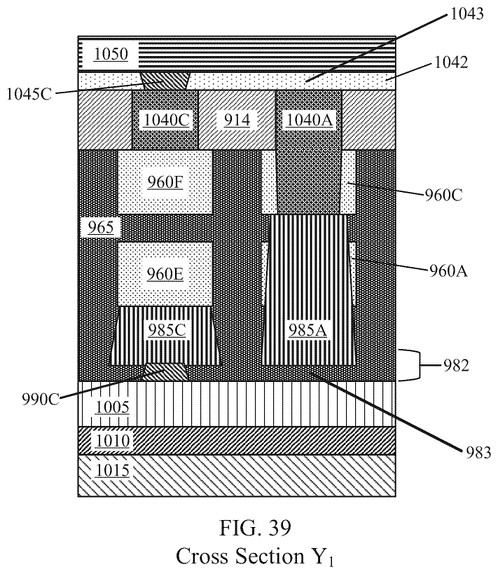

FIGS. 38-39 illustrate cross sections X and Y₁, respectively, of the plurality of nanodevices ND1, ND2 after ILD 965 and additional ILD 982 deposition, frontside isolation ILD 983 deposition, BILD layer 1020 and additional BILD layer 1042 deposition, backside isolation ILD 1043 deposition, nanosheet 920, 925, 935, 940 formation, STI region 914 formation, gate 955 formation, gate spacer 945 and inner spacer 950 formation, MDI layer 930 formation, source/drain 960A, 960B, 960C, 960D, 960E, 960F formation, protective liner 918 formation, source/drain contact 985A and independent source/drain contact 985B, 985C formation, backside source/drain contact 1040A and independent backside source/drain contact 1040B, 1040C formation, frontside via 990B, 990C and backside via 1045A, 1045C formation, BEOL layer 1005 formation, bonding oxide layer 1010 formation, carrier wafer 1015 formation, and backside interconnect 1050 formation, in accordance with the embodiment of the present invention. The frontside isolation ILD 983 is in direct contact with the frontside surface of the first source/drain contact 985A. The frontside via 990B connects to a frontside surface of the first independent source/drain contact 985B. The BEOL layer 1005 is in direct contact with a frontside surface of the frontside isolation ILD 983, a frontside surface of the frontside via 990B, and a frontside surface of a different frontside via 990C. The backside isolation ILD 1043 is in direct contact with the backside surface of the backside source/drain contact 1040A. The backside via 1045A connects to a backside surface of the first independent backside source/drain contact 1040B. The backside interconnect 1050 is in direct contact with a backside surface of the backside isolation ILD 1043, a backside surface of the backside via 1045A, and a backside surface of a different backside via 1045C.

It may be appreciated that FIGS. 1-39 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first nanodevice including a plurality of first upper transistors and a plurality of first lower transistors, wherein the first nanodevice includes a first upper source/drain and a first lower source/drain; and
a first source/drain contact extending upwards through the first upper source/drain and a backside source/drain contact extending downwards through the first lower source/drain, wherein the first source/drain contact directly connects to the backside source/drain contact to form a shared source/drain contact, wherein the first source/drain contact progressively narrows from a frontside surface to a backside surface of the first source/drain contact, and wherein the backside source/drain contact progressively narrows from a backside surface to a frontside surface of the backside source/drain contact.

2. The semiconductor device of claim 1, further comprising:
a first frontside via connected to the frontside surface of the first source/drain contact; and
a first backside via connected to the backside surface of the backside source/drain contact.

3. The semiconductor device of claim 2, further comprising:
a back-end-of-line (BEOL) layer connected to a frontside surface of the first frontside via; and
a backside interconnect connected to a backside surface of the first backside via.

4. The semiconductor device of claim 1, wherein the first source/drain contact is comprised of a first conductive metal and the backside source/drain contact is comprised of a second conductive metal, and wherein the first conductive metal is different from the second conductive metal.

5. The semiconductor device of claim 4, further comprising:
a first frontside via connected to the frontside surface of the first source/drain contact;
a BEOL layer connected to a frontside surface of the first frontside via;
a first backside via connected to the backside surface of the backside source/drain contact; and
a backside interconnect connected to a backside surface of the first backside via.

6. The semiconductor device of claim 4, further comprising:
a first backside via connected to the backside surface of the backside source/drain contact;
a backside interconnect connected to a backside surface of the first backside via;
a frontside isolation interlayer dielectric (ILD) in direct contact with the frontside surface of the first source/drain contact; and
a BEOL layer in direct contact with a frontside surface of the frontside isolation ILD.

7. The semiconductor device of claim 4, further comprising:
a first frontside via connected to the frontside surface of the first source/drain contact;
a BEOL layer connected to a frontside surface of the first frontside via;
a backside isolation ILD in direct contact with the backside surface of the backside source/drain contact; and
a backside interconnect in direct contact with a backside surface of the backside isolation ILD.

8. The semiconductor device of claim 4, further comprising:
a frontside isolation ILD in direct contact with the frontside surface of the first source/drain contact;
a BEOL layer in direct contact with a frontside surface of the frontside isolation ILD;
a backside isolation ILD in direct contact with the backside surface of the backside source/drain contact; and
a backside interconnect in direct contact with a backside surface of the backside isolation ILD.

9. A semiconductor device comprising:
a first nanodevice including a plurality of first upper transistors and a plurality of first lower transistors, wherein the first nanodevice includes a first upper source/drain, a second upper source/drain, a first lower source/drain, and a second lower source/drain;
a first source/drain contact extending upwards through the first upper source/drain and a backside source/drain contact extending downwards through the first lower source/drain, wherein the first source/drain contact directly connects to the backside source/drain contact to form a shared source/drain contact, wherein the first source/drain contact progressively narrows from a frontside surface to a backside surface of the first source/drain contact, and wherein the backside source/drain contact progressively narrows from a backside surface to a frontside surface of the backside source/drain contact; and
a first independent source/drain contact connected to a frontside surface of the second upper source/drain and a first independent backside source/drain contact connected to a backside surface of the second lower source/drain.

10. The semiconductor device of claim 9, further comprising:
a first frontside via connected to the frontside surface of the first source/drain contact and a second frontside via connected to a frontside surface of the first independent source/drain contact; and
a first backside via connected to the backside surface of the backside source/drain contact and a second backside via connected to a backside surface of the first independent backside source/drain contact.

11. The semiconductor device of claim 10, further comprising:
a BEOL layer connected to a frontside surface of the first frontside via and a frontside surface of the second frontside via; and
a backside interconnect connected to a backside surface of the first backside via and a backside surface of the second backside via.

12. The semiconductor device of claim 9, wherein the first source/drain contact and the first independent source/drain contact are comprised of a first conductive metal, wherein the backside source/drain contact and the first independent backside source/drain contact are comprised of a second conductive metal, and wherein the first conductive metal is different from the second conductive metal.

13. The semiconductor device of claim 12, further comprising:
a first frontside via connected to the frontside surface of the first source/drain contact and a second frontside via connected to a frontside surface of the first independent source/drain contact;
a BEOL layer connected to a frontside surface of the first frontside via and a frontside surface of the second frontside via;
a first backside via connected to the backside surface of the backside source/drain contact and a second backside via connected to a backside surface of the first independent backside source/drain contact; and
a backside interconnect connected to a backside surface of the first backside via and a backside surface of the second backside via.

14. The semiconductor device of claim 12, further comprising:
a first backside via connected to the backside surface of the backside source/drain contact and a second backside via connected to a backside surface of the first independent backside source/drain contact;
a backside interconnect connected to a backside surface of the first backside via and a backside surface of the second backside via;
a frontside isolation ILD in direct contact with the frontside surface of the first source/drain contact;
a frontside via connected to a frontside surface of the first independent source/drain contact; and
a BEOL layer in direct contact with a frontside surface of the frontside isolation ILD and a frontside surface of the frontside via.

15. The semiconductor device of claim 12, further comprising:
a first frontside via connected to the frontside surface of the first source/drain contact and a second frontside via connected to a frontside surface of the first independent source/drain contact;
a BEOL layer connected to a frontside surface of the first frontside via and a frontside surface of the second frontside via;
a backside isolation ILD in direct contact with the backside surface of the backside source/drain contact;
a backside via connected to a backside surface of the first independent backside source/drain contact; and
a backside interconnect in direct contact with a backside surface of the backside isolation ILD and a backside surface of the backside via.

16. The semiconductor device of claim 12, further comprising:
a frontside isolation ILD in direct contact with the frontside surface of the first source/drain contact;
a frontside via connected to a frontside surface of the first independent source/drain contact;
a BEOL layer in direct contact with a frontside surface of the frontside isolation ILD and a frontside surface of the frontside via;
a backside isolation ILD in direct contact with the backside surface of the backside source/drain contact;
a backside via connected to a backside surface of the first independent backside source/drain contact; and
a backside interconnect in direct contact with a backside surface of the backside isolation ILD and a backside surface of the backside via.

17. A semiconductor device comprising:
a first nanodevice including a plurality of first upper transistors and a plurality of first lower transistors, wherein the first nanodevice includes a first upper source/drain, a second upper source/drain, a first lower source/drain, and a second lower source/drain;
a second nanodevice including a plurality of second upper transistors and a plurality of second lower transistors, wherein the second nanodevice is located adjacent to and parallel to the first nanodevice, wherein the second nanodevice includes a third upper source/drain and a third lower source/drain;
a first source/drain contact extending upwards through the first upper source/drain and a backside source/drain contact extending downwards through the first lower source/drain, wherein the first source/drain contact directly connects to the backside source/drain contact to form a shared source/drain contact, wherein the first source/drain contact progressively narrows from a frontside surface to a backside surface of the first source/drain contact, and wherein the backside source/drain contact progressively narrows from a backside surface to a frontside surface of the backside source/drain contact; and
a first independent source/drain contact and a second independent source/drain contact connected to a frontside surface of the second upper source/drain and the third upper source/drain, respectively, and a first independent backside source/drain contact and a second independent backside source/drain contact connected to a backside surface of the second lower source/drain and the third lower source/drain, respectively.

18. The semiconductor device of claim 17, further comprising:
a first frontside via connected to the frontside surface of the first source/drain contact, a second frontside via connected to a frontside surface of the first independent source/drain contact, and a third frontside via connected to a frontside surface of the second independent source/drain contact; and
a first backside via connected to the backside surface of the backside source/drain contact, a second backside via connected to a backside surface of the first independent backside source/drain contact, and a third backside via connected to a backside surface of the second independent backside source/drain contact.

19. The semiconductor device of claim 18, further comprising:
a BEOL layer connected to a frontside surface of the first frontside via, a frontside surface of the second frontside via, and a frontside surface of the third frontside via; and
a backside interconnect connected to a backside surface of the first backside via, a backside surface of the second backside via, and a backside surface of the third backside via.

20. The semiconductor device of claim 17, wherein the shared source/drain contact extends a first height perpendicular to a y-axis, wherein the first independent source/drain contact and the first independent backside source/drain contact each extend a second height perpendicular to the y-axis, and wherein the first height is greater than the second height.
